(19) United States
(12) Patent Application Publication
(10) Pub. No.: US 2019/0131384 A1
(43) Pub. Date: May 2, 2019

(54) FERROELECTRIC TUNNEL JUNCTION STRUCTURE AND METHOD OF FABRICATING THE SAME

(71) Applicant: NATIONAL UNIVERSITY OF SINGAPORE, Singapore (SG)

(72) Inventors: Jingsheng CHEN, Singapore (SG); Rui GUO, Singapore (SG)

(73) Assignee: NATIONAL UNIVERSITY OF SINGAPORE, Singapore (SG)

(21) Appl. No.: 16/171,419

(22) Filed: Oct. 26, 2018

(30) Foreign Application Priority Data
Oct. 27, 2017 (SG) 10201708853S

(51) Int. Cl. H01L 49/02; H01L 27/11507; G06N 99/00

(52) U.S. Cl. CPC H01L 28/55; G06N 99/002; H01L 27/11507; H01L 28/65

(57) ABSTRACT

A ferroelectric tunnel junction (FTJ) structure and method of fabricating the same. The FTJ structure comprises a ferroelectric material formed on a substrate, wherein an interface between the ferroelectric material and the substrate is configured so as to achieve a desired resistance characteristic of the FTJ structure.

### CROSS-REFERENCE TO RELATED APPLICATION

This application claims the benefit of priority of Singapore Patent Application No. 10201708853S filed on Oct. 27, 2017, the content of which is incorporated herein by reference in its entirety for all purposes.

### FIELD OF INVENTION

The present invention relates broadly to a ferroelectric tunnel junction structure and a method of fabricating the same, and in particular to BaTiO3 on Nb:SrTiO3 structures.

### BACKGROUND

Any mention and/or discussion of prior art throughout the specification should not be considered, in any way, as an admission that this prior art is well known or forms part of common general knowledge in the field.

Ferroelectric tunnel junctions (FTJs) devices are promising for various applications, e.g. for resistive random access memory (RRAM) applications. For such applications, it is desired to achieve a high tunneling electroresistance (TER) ratio, as this increases the possibility of the devices being used for multilevel cell storage.

In resistive switching based on redox reaction of metal oxides in existing devices, electroforming process is needed to achieve stable resistive switching. No variation in resistance characteristics after the electroforming process has been reported for such devices.

Also, RRAM and phase change memory (PCM) have been considered as promising candidates for synaptic devices [2, 3]. However, the devices in existing studies have the shortcoming of discrete and abrupt resistive switching characteristic, which is caused by the filament formation process, preventing them from being utilized e.g. in large neural network systems.

Embodiments of the present invention seek to address at least one of the above problems.

### SUMMARY

In accordance with a first aspect of the present invention, there is provided a ferroelectric tunnel junction (FTJ) structure comprising a ferroelectric material formed on a substrate, wherein an interface between the ferroelectric material and the substrate is configured so as to achieve a desired resistance characteristic of the FTJ structure.

In accordance with a second aspect of the present invention, there is provided method of fabricating a ferroelectric tunnel junction (FTJ) structure, the method comprising forming a ferroelectric material on a substrate, and configurating an interface between the ferroelectric material and the substrate so as to achieve a desired resistance characteristic of the FTJ structure.

### BRIEF DESCRIPTION OF THE DRAWINGS

FIG. 1A shows a step in the fabrication of an FTJ structure according to example embodiments.

FIG. 1B shows a step in the fabrication of an FTJ structure according to example embodiments.

FIG. 1C shows a step in the fabrication of an FTJ structure according to example embodiments.

FIG. 1D shows a step in the fabrication of an FTJ structure according to example embodiments.

FIG. 1E shows a step in the fabrication of an FTJ structure according to example embodiments.

FIG. 1F shows a step in the fabrication of an FTJ structure according to example embodiments.

FIG. 2A shows the typical I-V curves of A-type tunnelling devices according to example embodiments in the low bias regime (−0.3 to 0.3 V).

FIG. 2B shows the I-V switching curves measured by sweeping the voltage pulse applied to the devices from −7 to 0 V, then 0 to 6 V, and finally back to −7 V, of A-type tunnelling devices according to example embodiments.

FIG. 2C shows typical R-V hysteresis loops measured with increasing negative voltage pulses applied to the devices from −3 to −7 V for A-type devices according to example embodiments.

FIG. 2D shows the typical I-V curves of B-type tunnelling devices according to example embodiments in the low bias regime (−0.3 to 0.3 V).

FIG. 2E shows the I-V switching curves measured by sweeping the voltage pulse applied to the devices from −7 to 0 V, then 0 to 6 V, and finally back to −7 V, of B-type tunnelling devices according to example embodiments.

FIG. 2F shows typical R-V hysteresis loops measured with increasing negative voltage pulses applied to the devices from −3 to −7 V for B-type devices according to example embodiments.

FIG. 3A shows pulse-driven conductance change of the A-type memristor devices according to example embodiments.

FIG. 3B shows pulse-driven conductance change of the B-type memristor devices according to example embodiments.

FIG. 3C shows the typical antisymmetric Hebbian learning rule of an A-type ferroelectric memristor according to an example embodiment.

FIG. 3D shows the typical antisymmetric anti-Hebbian learning rule of an A-type ferroelectric memristor according to an example embodiment.

FIG. 3E shows the typical antisymmetric Hebbian learning rule of a B-type ferroelectric memristor according to an example embodiment.

FIG. 3F shows the typical antisymmetric anti-Hebbian learning rule of a B-type ferroelectric memristor according to an example embodiment.

FIG. 4 shows a schematic drawing illustrating a ferroelectric tunnel junction according to an example embodiment.

FIG. 5 shows a flowchart illustrating a method of fabricating a ferroelectric tunnel junction structure according to an example embodiment.

### DETAILED DESCRIPTION

Embodiments of the present invention demonstrate synaptic behaviors in Pt/BaTiO₃/Nb:SrTiO₃ ferroelectric tunnel memristors, in which the Nb:SrTiO₃ (NSTO) bottom electrode has two different terminations, TiO₂- (A-type) and SrO- (B-type) termination, respectively. The effect of the different interfaces on the device performance, such as the current transport property, the memristor behavior, and the synaptic properties, were studied for the example embodiments. Different terminations of the substrate result in different self-polarization directions of BaTiO₃ (BTO) thin films, and thus the opposite ON or OFF virgin resistance state of the memristor devices. Different interfaces of the devices cause different Schottky barrier heights at the BTO/NSTO interface, which leads to different memristive behavior of two types of devices according to example embodiments. Memristor devices grown on TiO₂-terminated NSTO substrates (A-type devices according to example embodiments) possess bidirectional continuous conductance modulation characteristic. Gradual resistance modulation up to seven orders of magnitude could be achieved by applying voltage pulses with different polarity and amplitude, according to example embodiments.

Due to the good memristive behavior, A-type devices according to example embodiments could emulate the synaptic functions very well. Four spike-timing-dependent plasticity (STDP) forms were demonstrated according to example embodiments by applying programmed pre- and postsynaptic spiking pulse pairs in different time windows. In contrast, memristor devices on SrO-terminated substrates (B-type devices according to example embodiments) only have unidirectional continuous conductance modulation characteristic. They therefore show reduced STDP properties compared with A-type devices.

Embodiments of the present invention can provide new opportunities for neuromorphic computing. A-type memristor devices according to example embodiments have promising potentials for future synaptic devices. In order to be stacked on top of a CMOS underlayer, a memristor preferably has a small device size with a large ON/OFF ratio. Ideally, the functional device size of the ferroelectric tunnel junction according to example embodiments can be as small as lithography technique allows, since the conductance advantageously does not depend on the lateral size of the capacitor. The giant ON/OFF ratio of the ferroelectric tunnel memristor with good STDP properties according to example embodiments provides new opportunities for neuromorphic computing. Additionally, example embodiments of the present invention also give important insight and reference in the effect of the terminations on the memristive behavior of the ferroelectric tunnel memristor.

### Sample Preparation According to Example Embodiments:

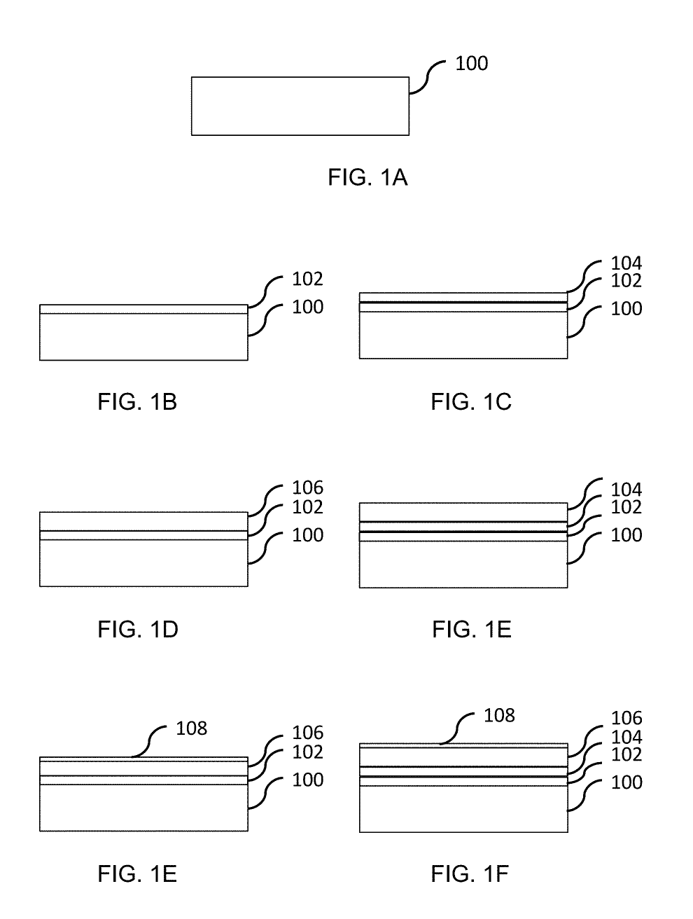

BTO thin films with the thickness of 5 unit-cell were deposited by pulsed laser deposition (PLD) technique on NSTO substrates. With reference to FIG. 1A, NSTO substrates 100 were treated before the film deposition. To get a TiO₂-terminated surface 102 as shown in FIG. 1B, a buffered HF acid etching process was done followed by a thermal treatment at 950° C. The SrO termination was obtained by growing one unit cell of SrRuO₃ (SRO) layer 104 on top of treated TiO₂-terminated NSTO substrates using an SrRuO₃ target, as shown in FIG. 1C. The one unit cell SRO layer 104 was deposited with a substrate temperature of 750° C. and an oxygen pressure of 10 mTorr. BTO films 106 were deposited at a substrate temperature of 600° C. with an oxygen partial pressure of 5 mTorr, as shown in FIGS. 1D and E. After the deposition, the films 106 were cooled down to room temperature at an oxygen pressure of 100 Torr. The cooling rate was 5° C./min till 300° C., and then 10° C./min to room temperature. The top Pt electrode 108 was deposited using sputtering at room temperature, as shown in FIGS. 1F and G. In this embodiment, the NSTO substrate 100 also functions as the bottom electrode.

### Results and Analysis of Example Embodiments:

Piezoresponse force microscopy (PFM) was performed to characterize the virgin polarization state of the as grown BTO thin films according to example embodiments. The virgin state of BTO thin films grown on TiO₂- or SrO-terminated NSTO substrates is downward (i.e. towards the NSTO substrate) and upward (i.e. away from the NSTO substrate), respectively. After applying a bias of −4 V or +4 V, the respective virgin downward or upward BTO polarizations were switched to their opposite directions, and then were switched back to their original directions again if opposite bias was applied.

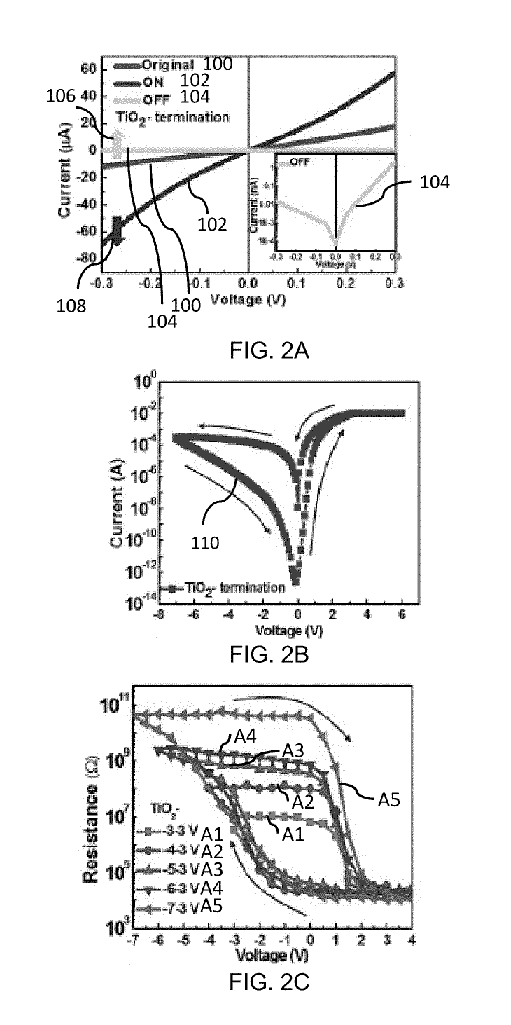

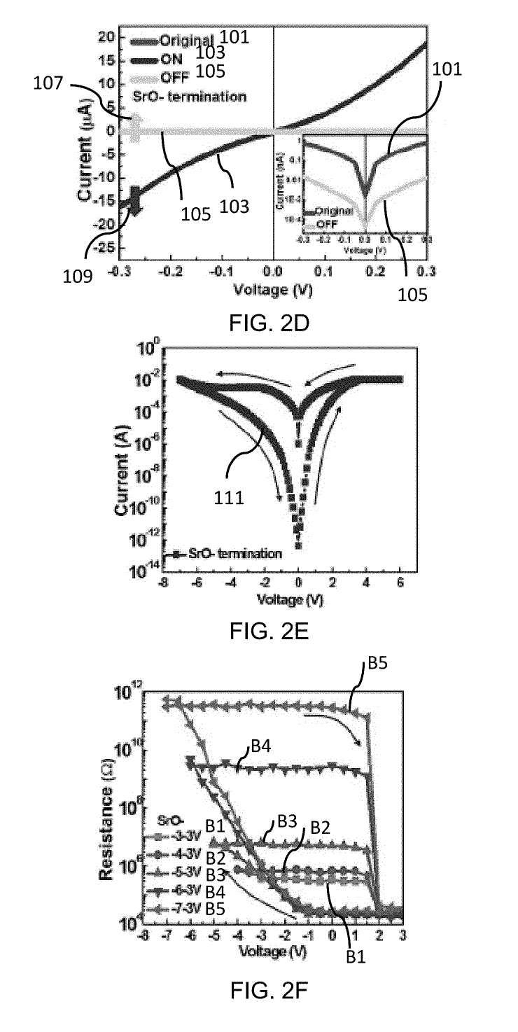

To compare the basic properties of the two (A- and B-) types of tunnelling devices according to example embodiments, their current-voltage (I-V) curves were measured at room temperature. The applied voltage is termed as positive (negative) if a positive (negative) bias is applied to the top Pt electrode. FIGS. 2A and D show the typical I-V curves of A- and B-type tunnelling devices, respectively, according to example embodiments in the low bias regime (−0.3 to 0.3 V). In FIGS. 2A and D, the lines 200 and 201 (see inset in FIG. 2D, noting that curve 201 is hidden below curve 105 in the linear scale resolution of FIG. 2D) represent the I-V curves of the virgin state of A- and B-type tunnelling devices, respectively, according to example embodiments, while the lines 202 and 203 represent the I-V curves after a bias of +4 V, and the lines 204 and 205 represent the I-V curves after a bias of −7 V was applied to the A- and B-types of devices, respectively, according to example embodiments.

Due to the downward and upward virgin states of the BTO polarization, the I-V curves (lines 200 and 201) of the virgin state of A- and B-type devices according to example embodiments reveal a tunnelling ON and OFF state, respectively. After applying a bias of +4 V or −7 V to the devices with a pulse width of 0.1 ms, the BTO polarization of the device was switched to downward (+4 V) or upward (−7 V) irrespective of its virgin state, and its corresponding I-V curve displays a tunnelling ON (lines 202 and 203) and OFF (lines 204 and 205) state, respectively. The log scale representation of the OFF state I-V curves (lines 204 and 205) of A- and B-type devices are shown in the insets of FIGS. 2A and D, respectively. It can be seen that the OFF state I-V curve (line 204) of A-type devices displays an obvious diode effect, while the OFF state I-V curves (lines 201 and 205) of B-type devices are quite symmetric. Different I-V curve shapes of the A- and B-types of devices are also revealed in their I-V switching curves (lines 210 and 211), as shown in FIGS. 2B and E, respectively. Clear resistive switching behaviour was observed in both A- and B-types of devices according to example embodiments with the positive (negative) voltage leading to low (high) resistance state.

In FIGS. 2A and D the arrows 206 and 207 represent the polarization of the BTO layer to be upward and the arrows 208 and 209 represent the polarization of BTO layer to be downward, which correspond to the OFF (lines 204 and 205) and ON (lines 202 and 203) state of the memristive device, respectively. The curves show the fitted I-V data results. In FIGS. 2B and E the I-V switching curves 210 and 211 were measured by sweeping the voltage pulse applied to the devices from −7 to 0 V, then 0 to 6 V, and finally back to −7 V.

R-V curves were measured by sweeping the voltage pulse applied to the devices from −7 (−6, −5, −4, −3) to 0 V, then 0 to 3 V, and finally back to −7 V (−6, −5, −4, −3), and the resistance of the ferroelectric tunnel junction (FTJ) devices according to example embodiments was read at a bias of +0.2 V. Both A- and B-types of tunnel junctions according to example embodiments display a typical memristive behaviour controlled by voltage pulses. A series of intermediate resistance states can be obtained by applying different voltage biases. When increasing the negative and positive switching voltage to −7 and +4 V, an ON/OFF ratio as large as 10⁷ can be achieved for both A- and B-types of FTJ devices. FIGS. 2C and F show typical R-V hysteresis loops measured with increasing negative voltage pulses applied to the devices from −3 to −7 V for A- and B-type devices, respectively, according to example embodiments. Up to now, to the knowledge of the inventors this tunnelling electro-resistance effect (TER) ratio obtained in example embodiments of the present invention is the largest among all the reported FTJs. The characteristic of the large ON/OFF ratio of the devices according to example embodiments is particularly advantageous, since it increases the possibility of the devices being used for multilevel cell storage. Note that the OFF state to ON state transition of B-type memristor according to example embodiments is very abrupt compared with that of the A-type memristor, as illustrated e.g. by the steeper slope in curve B5 at the high to low resistance transition during the voltage sweep compared to curve A5. It is assumed this is mainly attributed to the different barrier height at the BTO/NSTO interface. The B-type memristor according to example embodiments needs to overcome much lower barrier height to achieve the ON state, and therefore it is relatively much easier and faster to achieve the ON state.

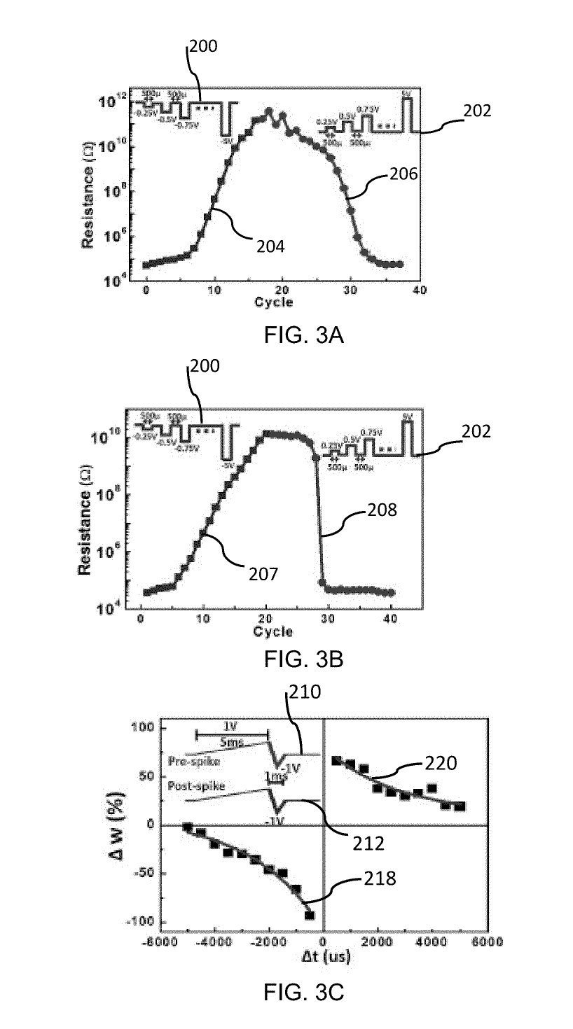

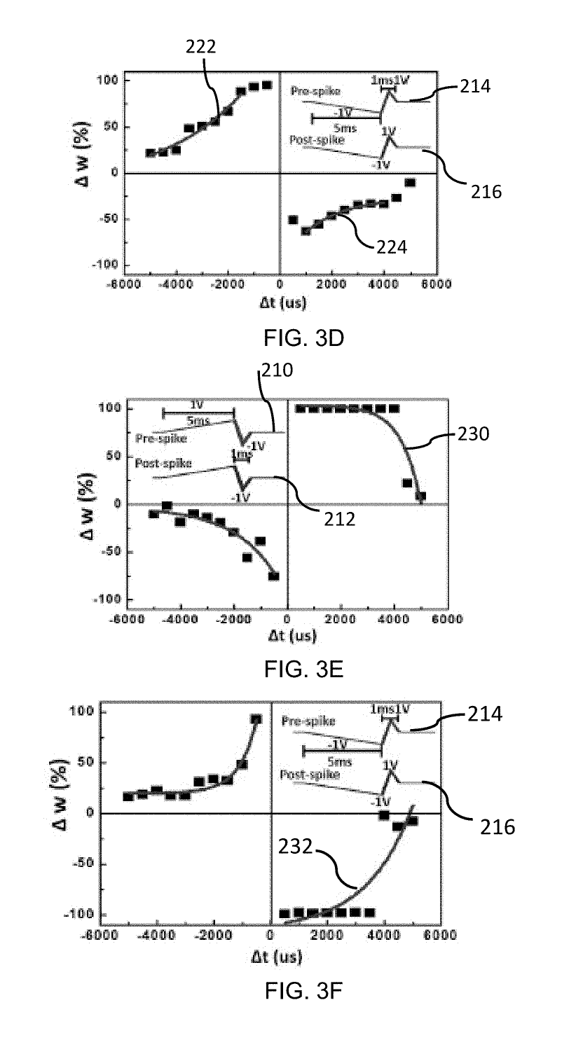

To emulate the synaptic weight modification, pulse-driven conductance change of the A- and B-types memristor devices according to example embodiments was measured, and the typical results are shown in FIGS. 3A and B, respectively. Programmed negative pulses (0-−5 V) 300 and positive pulses (0-5 V) 302 in sequential cycles with a step of 0.25 V were applied to the devices according to example embodiments to represent the depressing and potentiating spikes, respectively. The device resistance that could represent the device conductance was measured after each programming pulse at a small read voltage of +0.2 V. As shown in FIG. 3A, the conductance of A-type memristor increases (line 304) or decreases (line 306) gradually in response to increasing negative or positive pulses 300 and 302, respectively, representing synaptic weight modulation due to potentiating or depressing pulses, respectively. The resistance of A-type memristor displays a bidirectional gradual change in response to the programmed pulses 300 and 302. The ability of artificial synapses to possess bidirectional continuous conductance modulation is an advantageous precondition to enable their use in a large neuromorphic network [1]. Up to now, although resistive random access memory (RRAM) and phase change memory (PCM) have been considered as promising candidates for synaptic devices [2, 3], their shortcoming of discrete and abrupt resistive switching characteristic which is caused by the filament formation process prevents them from being utilized in large neural network systems. Therefore, the bidirectional continuous conductance modulation characteristic of A-type ferroelectric tunnel memristors according to example embodiments preferably provides promising potential for future synaptic devices.

The pulse-driven memristive behaviour of B-type memristor devices according to example embodiments was measured using the exact same parameters, and the typical result is shown in FIG. 3B. The devices according to example embodiments show a similar gradual resistance change, line 307, in response to the negative pulses 300. However, different from the A-type memristor example embodiments, in response to the positive pulses 302, B-type memristor devices according to example embodiments display an abrupt resistance change from OFF to ON state, see line 308, which is consistent with their R-V switching curves (compare FIG. 2E). B-type memristor devices according to example embodiments therefore can realize unidirectional continuous conductance modulation. In that regard, A-type memristors according to example embodiments may be superior to B-type memristors according to example embodiments. However, despite their difference in the conductance modulation characteristic, A- and B-type tunnel memristor devices according to example embodiments possess a stable virgin state, which is low resistance ON state and high resistance OFF state, respectively. Therefore, unlike conventional resistive switching based on redox reaction of metal oxides, electroforming process is not needed to achieve stable resistive switching in the two types of devices according to example embodiments. This advantage is important since forming process creates significant variations in resistance according to example embodiments, as discussed above with reference to FIGS. 2C and D.

The results of the pulse driven memristive behaviour suggest that the ferroelectric tunnel memristor devices according to example embodiments possess the capability to emulate the biological synapses, for example, the STDP function, which requires the change of synaptic weight to be a strong function of the timing of the pre/post-synaptic spikes. The results of the pulse driven memristive behaviour also suggest that the STDP properties of A- and B-type memristor devices according to example embodiments might be different due to their different pulse driven memristive behaviours. To confirm those assumptions, four different STDP forms of the two types of the memristors according to example embodiments were measured as the function of the spike timing difference by applying a typical spike paring protocol used in biological synaptic studies and in other electronic synapses. FIGS. 3C and D show the typical antisymmetric Hebbian learning rule and antisymmetric anti-Hebbian learning rule of an A-type ferroelectric memristor according to an example embodiment, respectively, with the insets showing the shapes of the applied pre- and post-synaptic spikes 310, 312 and 314, 316, respectively. For antisymmetric Hebbian learning rule and antisymmetric anti-Hebbian learning rule, STDP can be simplified using an exponential function:

Δw=Δe^{-Δt/s}+Δw₀, (1)

where Δw represents the measured change of the memristor synaptic weight, A is the scaling factor, Δt is the time interval of the pre- and post-synaptic spikes, and τ is the time constant of the STDP function. Δw₀ is a constant which represents a non-associative component of the synaptic change [4]. As shown in FIG. 3C, when the pre-synapse spikes 310 are applied before (after) the post-synapse spikes 312, the memristor synaptic weight increases (decreases), see fitted curves 318 and 320, respectively. Moreover, the change in the synaptic weight with the function of the spike timing difference Δt can be well fitted with the exponential functions 318, 320 and 322, 324, confirming that the synaptic STDP characteristics can be obtained in the ferroelectric memristor devices according to example embodiments. The positive and negative maximum amount of synaptic modification reached 70.15% and 93.54%, respectively, which reflects the very large window of the multiple memristive resistance status according to example embodiments. The evoked plasticity decreased to nearly zero with the increase of Δt.

FIGS. 3E and F show the typical antisymmetric Hebbian learning rule and antisymmetric anti-Hebbian learning rule of a B-type ferroelectric memristor according to example embodiments, respectively. Different from the A-type memristor embodiments, when Δt>0, there are abrupt changes of Δw in both learning rules, see fitted curves 330 and 332. This makes the STDP property of the B-type memristor embodiments less favorable than that of the A-type memristor embodiments. The abrupt change of Δw is consistent with the pulse driven memristive behaviour (FIG. 3B) and the R-V switching behaviour (FIG. 2F) of the B-type devices.

As described above, a ferroelectric tunnel memristor of Pt/BTO/NSTO with two different interfaces was demonstrated according to example embodiments. Different interfaces of the memristor devices according to different embodiments have a significant influence on their performance. Due to the different virgin polarization directions of BTO thin film caused by the different terminations of NSTO substrates, A-type memristor devices according to example embodiments have a virgin ON resistance state, whereas B-type memristor devices according to example embodiments possess a virgin OFF state instead. Different interfaces of the memristor devices according to different embodiments also result in different barrier heights at the bottom BTO/NSTO interface, and thus lead to different electron transport properties. A-type memristor devices according to example embodiments possess much larger Schottky barrier at BTO/NSTO interface than that of B-type memristor devices according to example embodiments. Multilevel resistance states with a large ON/OFF ratio up to 10⁷ could be obtained by applying voltage pulses with different polarity and amplitude for both the A and B-types of devices according to example embodiments. On the other hand, A-type memristor devices according to example embodiments possess bidirectional continuous resistance modulation characteristic, whereas B-type memristor devices according to example embodiments showed an abrupt resistance transition from ON to OFF state, and thus have unidirectional continuous resistance modulation property. The bidirectional resistance modulation characteristic of A-type memristor devices according to example embodiments enables them to be advantageously able to emulate synaptic functions. Four STDP forms were demonstrated well in A-type memristor devices according to example embodiments, while B-type memristor devices according to example embodiments showed inferior STDP properties. Example embodiments of the present invention provide new opportunities for neuromorphic computing. A-type memristors according to example embodiments have promising potentials for future synaptic devices. The results indicate promising potentials for ferroelectric tunnel memristors according to example embodiments to be used for future synaptic devices. Furthermore, the results provide essential insights into, and reference for, tailoring the electronic device functionalities by nano-scale interface engineering, according to example embodiments. The interface control described in the example embodiments is also expected to likely be achievable in other oxide thin film systems, such as different perovskite oxide thin films on SrTiO₃ substrates, for example BiFeO₃/SrTiO₃, in different embodiments.

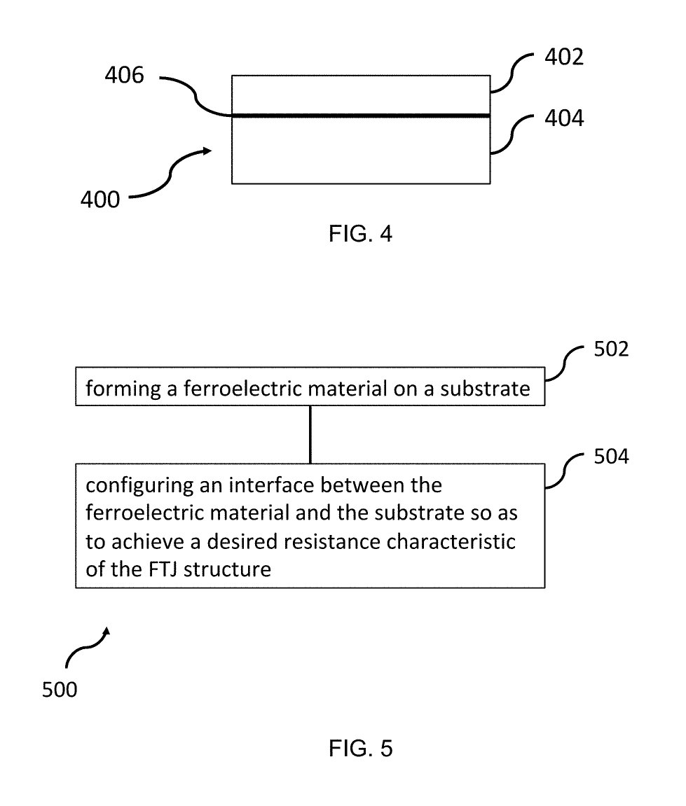

In one embodiment shown in FIG. 4, there is provided a ferroelectric tunnel junction (FTJ) structure 400 comprising a ferroelectric material 402 formed on a substrate 404, wherein an interface 406 between the ferroelectric material 402 and the substrate 404 is configured so as to achieve a desired resistance characteristic of the FTJ structure 400.

The interface 406 may comprise a termination of the substrate configured so as to achieve the desired resistance characteristic of the FTJ structure 400.

The interface 406 may be configured such that the ferroelectric material 402 exhibits a desired virgin polarization direction.

The interface 406 may be configured such that the FTJ structure 400 exhibits a desired resistance modulation property, preferably a bi-directional resistance modulation property for synaptic device applications.

The FTJ structure 400 may be configured such that a tunnelling electro-resistance effect (TER) ratio is substantially independent of the configuration of the interface 406. Preferably, the TER can be up to the order of 10⁷.

The FTJ structure 400 may exhibit spike-timing-dependent plasticity (STDP) properties. The FTJ structure 400 may exhibit four STDP forms.

The FTJ structure 400 may comprise Pt/BaTiO3/Nb:SrTiO3 (electrode/ferroelectric material/substrate). The substrate termination may comprise TiO₂-termination or SrO-termination.

FIG. 5 shows a flowchart 500 illustrating a method of fabricating a ferroelectric tunnel junction (FTJ) structure, according to an example embodiment. At step 502, a ferroelectric material is formed on a substrate. At step 504, an interface between the ferroelectric material and the substrate is configured so as to achieve a desired resistance characteristic of the FTJ structure.

Configuring the interface may comprise choosing a termination of the substrate so as to achieve the desired resistance characteristic of the FTJ structure.

The interface may be configured such that the ferroelectric material exhibits a desired virgin polarization direction.

The interface may be configured such that the FTJ structure exhibits a desired resistance modulation property, preferably a bi-directional resistance modulation property for synaptic device applications.

The FTJ structure may be configured such that a tunnelling electro-resistance effect (TER) ratio is substantially independent of the interface. Preferably, the TER can be up to the order of 10⁷.

The FTJ structure may exhibit spike-timing-dependent plasticity (STDP) properties. The FTJ structure may exhibit four STDP forms.

The FTJ structure may comprise Pt/BaTiO3/Nb:SrTiO3 (electrode/ferroelectric material/substrate). The substrate termination may comprise TiO₂-termination or SrO-termination.

The above description of illustrated embodiments of the systems and methods is not intended to be exhaustive or to limit the systems and methods to the precise forms disclosed. While specific embodiments of, and examples for, the systems components and methods are described herein for illustrative purposes, various equivalent modifications are possible within the scope of the systems, components and methods, as those skilled in the relevant art will recognize. The teachings of the systems and methods provided herein can be applied to other processing systems and methods, not only for the systems and methods described above.

The elements and acts of the various embodiments described above can be combined to provide further embodiments. These and other changes can be made to the systems and methods in light of the above detailed description.

In general, in the following claims, the terms used should not be construed to limit the systems and methods to the specific embodiments disclosed in the specification and the claims, but should be construed to include all processing systems that operate under the claims. Accordingly, the systems and methods are not limited by the disclosure, but instead the scope of the systems and methods is to be determined entirely by the claims.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list and any combination of the items in the list.

### REFERENCES

1. Yao, P. et al. Face classification using electronic synapses. 8, 15199 (2017).
2. Yu, S. et al. A Low Energy Oxide-Based Electronic Synaptic Device for Neuromorphic Visual Systems with Tolerance to Device Variation. Advanced Materials 25, 1774-1779, doi:10.1002/adma.201203680 (2013).
3. Kuzum, D., Jeyasingh, R. G. D., Lee, B. & Wong, H. S. P. Nanoelectronic Programmable Synapses Based on Phase Change Materials for Brain-Inspired Computing. Nano Letters 12, 2179-2186, doi:10.1021/n1201040y (2012).
4. Froemke, R. C. & Dan, Y. Spike-timing-dependent synaptic modification induced by natural spike trains. Nature 416, 433-438 (2002).

1. A ferroelectric tunnel junction (FTJ) structure comprising a ferroelectric material formed on a substrate, wherein an interface between the ferroelectric material and the substrate is configured so as to achieve a desired resistance characteristic of the FTJ structure.

2. The FTJ structure of claim 1, wherein the interface comprises a termination of the substrate configured so as to achieve the desired resistance characteristic of the FTJ structure.

3. The FTJ structure of claim 1, wherein the interface is configured such that the ferroelectric material exhibits a desired virgin polarization direction.

4. The FTJ structure of claim 1, wherein the interface is configured such that the FTJ structure exhibits a desired resistance modulation property.

5. The FTJ structure of claim 1, wherein the interface is configured such that the FTJ device exhibits a bi-directional resistance modulation property for synaptic device applications.

6. The FTJ structure of claim 1, wherein the FTJ structure is configured such that a tunnelling electro-resistance effect (TER) ratio is substantially independent of the configuration of the interface.

7. The FTJ structure of claim 6, wherein the TER is up to the order of 10⁷.

8. The FTJ structure of claim 1, wherein the FTJ structure exhibits spike-timing-dependent plasticity (STDP) properties.

9. The FTJ structure of claim 8, wherein the FTJ structure exhibits four STDP forms.

10. The FTJ structure of claim 1, wherein the FTJ structure comprises Pt/BaTiO3/Nb:SrTiO3 (electrode/ferroelectric material/substrate).

11. The FTJ structure of claim 10, wherein the substrate termination comprises TiO₂-termination or SrO-termination.

12. A method of fabricating a ferroelectric tunnel junction (FTJ) structure, the method comprising the steps of:
forming a ferroelectric material on a substrate, and
configuring an interface between the ferroelectric material and the substrate so as to achieve a desired resistance characteristic of the FTJ structure.

13. The method of claim 12, wherein configuring the interface comprises choosing a termination of the substrate so as to achieve the desired resistance characteristic of the FTJ structure.

14. The method of claim 12, wherein the interface is configured such that the ferroelectric material exhibits a desired virgin polarization direction.

15. The method of claim 12, wherein the interface is configured such that the FTJ structure exhibits a desired resistance modulation property.

16. The method of claim 15, wherein the interface is configured such that the FTJ device exhibits a bi-directional resistance modulation property for synaptic device applications.

17. The method of claim 12, wherein the FTJ structure is configured such that a tunnelling electro-resistance effect (TER) ratio is substantially independent of the interface.

18. The method of claim 17, wherein the TER is up to the order of 10⁷.

19. The method of claim 12, wherein the FTJ structure is configured to exhibit spike-timing-dependent plasticity (STDP) properties, and preferably to exhibit four STDP forms.

20. The method of claim 12, wherein the FTJ structure comprises Pt/BaTiO3/Nb:SrTiO3 (electrode/ferroelectric material/substrate), and preferably the substrate termination comprises TiO2 termination or SrO termination.
